(19) United States
(12) Patent Application Publication
(10) Pub. No.: US 2025/0273542 A1
(43) Pub. Date: Aug. 28, 2025

(54) SEMICONDUCTOR DEVICE

(71) Applicant: ABLIC Inc., Nagano (JP)

(72) Inventor: Kiyoaki KADOI, Nagano (JP)

(73) Assignee: ABLIC Inc., Nagano (JP)

(21) Appl. No.: 19/008,584

(22) Filed: Jan. 2, 2025

(30) Foreign Application Priority Data
Feb. 27, 2024 (JP) 2024-027715
Sep. 17, 2024 (JP) 2024-160017

(51) Int. Cl. H01L 23/495; H01L 23/00; H01L 23/31

(52) U.S. Cl. CPC H01L 23/49548; H01L 23/3121; H01L 23/49579; H01L 23/49513; H01L 24/32; H01L 24/48; H01L 24/73; H01L 2224/32245; H01L 2224/48091; H01L 2224/48245; H01L 2224/48465; H01L 2224/73265; H01L 2924/1815

(57) ABSTRACT

A semiconductor device 100 includes a semiconductor chip 110, a plurality of leads 102 arranged apart from each other around the semiconductor chip 110 in a plan view and extending from the semiconductor chip 110 side, an encapsulating resin 140 forming an outer shape such that at least lower surfaces and end faces of the plurality of leads 102 are respectively exposed, and a metal film 150 formed on a lower surface of the lead 102. A lower surface of the lead 102 is formed at a position above a lower surface of the encapsulating resin 140.

### CROSS-REFERENCE TO RELATED APPLICATION

This application claims the priority benefits of Japanese application no. 2024-027715, filed on Feb. 27, 2024, and Japanese application no. 2024-160017, filed on Sep. 17, 2024. The entirety of the above-mentioned patent application is hereby incorporated by reference herein and made a part of this specification.

### BACKGROUND

### Technical Field

The present invention relates to a semiconductor device.

### Description of Related Art

As electronic machines such as mobile phones and mobile machines become more functional, there is an increasing demand for miniaturization and thinning of semiconductor devices used in such electronic machines.

A common package for a semiconductor device formed by molding epoxy resin includes a structure in which a semiconductor chip is mounted on a die pad, which is part of a lead frame, and covered with epoxy resin to form an outer shape. One form of such a small package structure is a non-lead type DFN (Dual Flat Nonleaded) package.

In general, a DFN package is resin-encapsulated such that the lower surface of the lead is almost flush with the lower surface of the encapsulating resin, and the lower surface of the lead is exposed. Subsequently, a plating layer is formed on the lower surface of the lead, and the lead frame is singulated by cutting with a dicing device. The DFN package manufactured in this way functions with the lower surface of the lead, on which the plating layer is formed, as an outer lead.

As described above, in the case of a DFN package, when only the lower surface of the lead with the plating layer is bonded to the mounting substrate with solder or the like, it is difficult to secure sufficient bonding strength between the lead and the mounting substrate.

To suppress the decrease in bonding strength between the lead and the mounting substrate, for example, the invention described in Patent Document 1 (Japanese Patent Application Laid-Open (JP-A) No. 2000-294719) describes a semiconductor device in which an elongated groove-like recess is formed on the lower surface of the lead.

One aspect of the present invention provides a semiconductor device including a lead that may ensure bonding reliability with a mounting substrate even in a non-lead type package.

### SUMMARY

A semiconductor device according to one embodiment of the present invention includes:
a semiconductor chip;
a plurality of leads arranged apart from each other around the semiconductor chip in a plan view and extending from the semiconductor chip side;
an encapsulating resin forming an outer shape such that at least lower surfaces and end faces of the plurality of leads are respectively exposed; and
a metal film formed on a lower surface of the lead.

A lower surface of the lead is formed at a position above a lower surface of the encapsulating resin.

### BRIEF DESCRIPTION OF THE DRAWINGS

FIG. 1 is a schematic top view (perspective view) of the semiconductor device according to the first embodiment of the present invention.

FIG. 2A is a schematic side view (perspective view) of the semiconductor device illustrated in FIG. 1.

FIG. 2B is an enlarged view of part A in FIG. 2A.

FIG. 3 is a diagram illustrating the manufacturing process of the semiconductor device according to the embodiment of the present invention.

FIG. 4 is a diagram illustrating the manufacturing process of the semiconductor device according to the embodiment of the present invention, continuing from FIG. 3.

FIG. 5 is a diagram illustrating the manufacturing process of the semiconductor device according to the embodiment of the present invention, continuing from FIG. 4.

FIG. 6A is a schematic side view (perspective view) illustrating the semiconductor device according to the second embodiment of the present invention.

FIG. 6B is an enlarged view of part B in FIG. 6A.

FIG. 7A is a schematic side view (perspective view) of a conventional semiconductor device.

FIG. 7B is an enlarged view (schematic diagram) of part C in FIG. 7A in the case where a conventional semiconductor device is bonded to a mounting substrate.

### DESCRIPTION OF THE EMBODIMENTS

The embodiments for implementing the present invention are described in detail below with reference to the drawings. In addition, in the drawings, the same component parts may be given the same signs, and redundant explanations may be omitted.

Further, the X-axis, Y-axis and Z-axis shown in the drawings are assumed to be orthogonal to each other. The Z-axis direction may be referred to as “height direction” or “thickness direction.” The +Z-axis direction may be referred to as “upward”, and the −Z-axis direction may be referred to as “downward”. The surface on the +Z direction side of each component may be referred to as the “front surface” or “upper surface”, and the surface on the −Z direction side may be referred to as the “back surface” or “lower surface”. “Plan view” refers to viewing each component from the +Z direction side toward the −Z direction side. “Side view” refers to viewing each component transparently from the +Y direction side toward the −Y direction side.

Further, the drawings are schematic, and the width, depth, thickness ratio, etc. are not as shown. The quantity, position, shape, structure, size, etc. of each component are not limited to the embodiments shown below, but may be any quantity, position, shape, structure, size, etc. that is desirable in implementing the present invention.

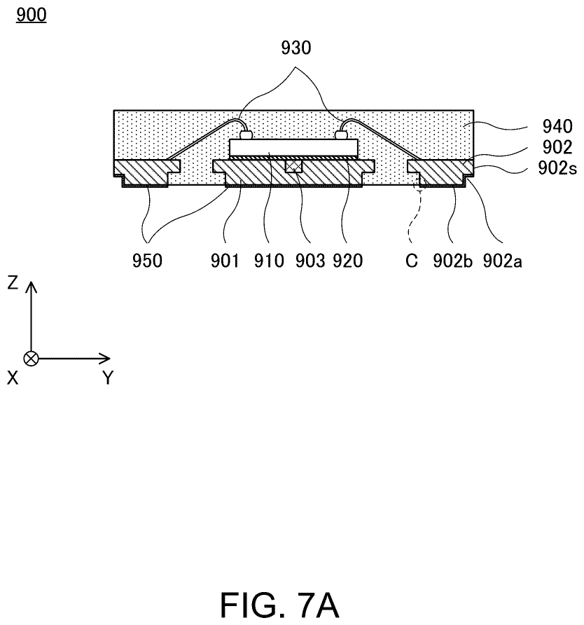

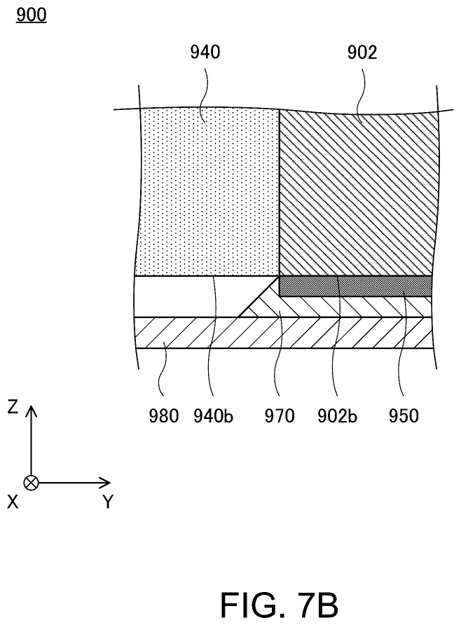

FIG. 7A is a schematic side view (perspective view) of a conventional semiconductor device. As illustrated in FIG. 7A, in the conventional semiconductor device 900 of a DFN package, electrodes on the surface of a semiconductor chip 910 fixed to a die pad 901 with a conductive adhesive 920 are electrically connected to a plurality of leads 902 respectively by conductive wires 930. A step portion 902a is formed at the corner portion between the lower surface 902b of the lead 902 and the end face 902s of the lead. An encapsulating resin 940 forms the outer shape of the semiconductor device 900 such that at least parts of the plurality of leads 902 are exposed. The die pad 901 and the plurality of leads 902 are formed of a metal material such as a copper alloy.

FIG. 7B is an enlarged view (schematic diagram) of part C in FIG. 7A in the case where a conventional semiconductor device is bonded to a mounting substrate. The lower surface 902b of the lead 902 is formed on the same plane as the lower surface 940b of the encapsulating resin 940. A metal film 950 is formed on the lower surface 902b of the lead 902. This metal film 950 is formed of a material with good solder wettability and is bonded to a mounting substrate 980 by solder 970.

In conventional DFN packages as shown in FIG. 7A and FIG. 7B, it is common for the lower surface 902b of the lead to be formed almost on the same plane as the lower surface 940b of the encapsulating resin, and the interface between the lead 902 and the metal film 950 has a structure that is flush with the lower surface 940b of the encapsulating resin. Further, solder 970 is formed at the end portion of the interface between the lead 902 and the metal film 950.

In such a structure, in response to conducting a reliability test that repeats temperature changes between high and low temperatures, stress generated due to differences in thermal expansion coefficients among the lead 902, encapsulating resin 940, and mounting substrate 980 concentrates at the interface between the lead 902 and the metal film 950. This stress may cause cracks to occur at the interface between the lead 902 and the metal film 950. The same applies to other non-lead type packages in the case where the lower surface of the lead and the lower surface of the encapsulating resin are formed almost on the same plane.

Thus, the semiconductor device according to one embodiment of the present invention forms the lower surface of the lead at a position above the lower surface of the encapsulating resin. As a result, it is possible to suppress the occurrence of cracks at the interface between the lead and the metal film, and provide a semiconductor device including a lead that may ensure bonding reliability with the mounting substrate even in a non-lead type package.

### First Embodiment

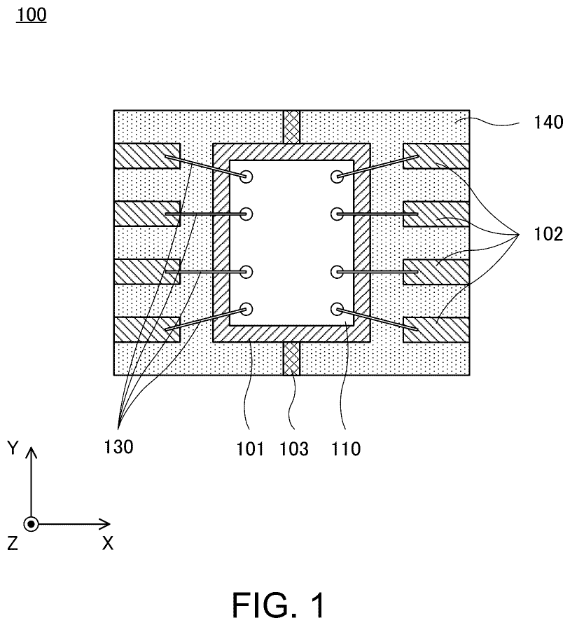

FIG. 1 is a schematic top view (perspective view) of the semiconductor device according to the first embodiment of the present invention. As illustrated in FIG. 1, the semiconductor device 100 according to the first embodiment of the present invention includes a semiconductor chip 110, a plurality of leads 102, and an encapsulating resin 140.

The semiconductor chip 110 is a semiconductor chip for enabling the function of the semiconductor device 100, and is mounted on the upper surface of the die pad 101 by being fixed with a conductive adhesive or the like. The plurality of leads 102 are arranged at a constant distance apart from each other on two opposing sides in the +X direction and-X direction of the die pad 101 in plan view.

The plurality of electrode pads (not shown) formed on the upper surface of the semiconductor chip 110 are electrically connected to the upper surfaces of the plurality of leads 102 by conductive wires 130. The upper surface of the lead 102 is formed as a smooth surface. Thus, a wide area may be secured on the upper surface of the lead 102 for performing a second bond of the conductive wire 130. This allows for securing the bonding area for wire bonding and may suppress the decrease in connection strength. The conductive wire 130 is, for example, a gold wire or a copper wire.

The hanging portions 103 extend from two sides of the die pad 101 in the +Y direction and −Y direction. It is noted that in this embodiment, the die pad 101, the plurality of leads 102, and the hanging portions 103 are formed of the same copper alloy material and have an integrated lead frame structure. FIG. 1 illustrates one combination that forms one semiconductor device. It is ultimately divided into individual semiconductor devices.

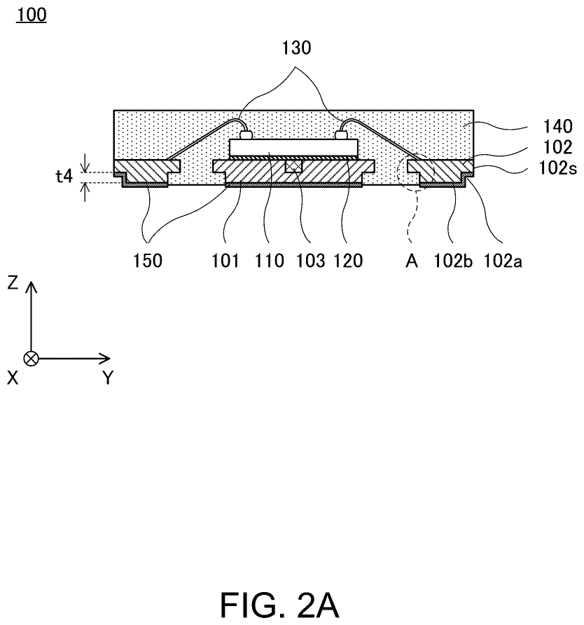

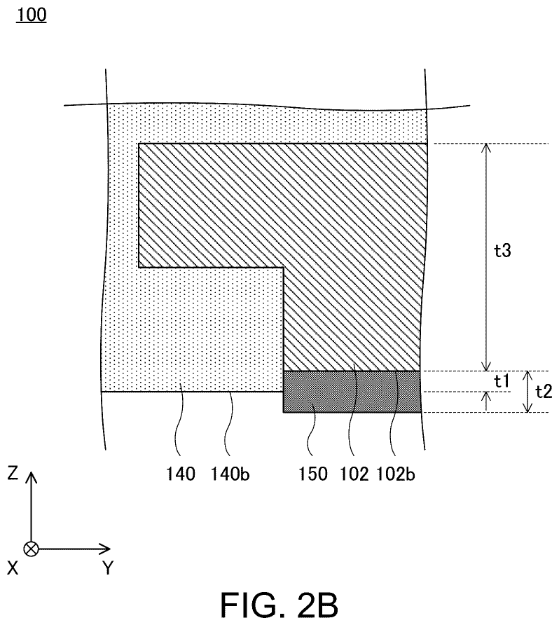

FIG. 2A is a schematic side view (perspective view) of the semiconductor device illustrated in FIG. 1. As illustrated in FIG. 2A, the semiconductor chip 110 is mounted on the upper surface of the die pad 101 by being fixed with a conductive adhesive 120. A metal film 150 is formed on the lower surface of the die pad 101 and is exposed from the encapsulating resin 140 to improve the heat dissipation of the semiconductor chip 110. The periphery of the lower surface of the die pad 101 is formed to be thin. This creates a structure where the encapsulating resin 140 enters the lower surface around the die pad 101, preventing the die pad 101 from falling out of the encapsulating resin 140.

The side of the lead 102 near the die pad 101 is formed to be thin on the lower surface. This creates a structure where the encapsulating resin 140 enters the lower surface of the lead 102 on the die pad 101 side, preventing the lead 102 from falling out of the encapsulating resin 140. The end face 102s in the extending direction of the lead 102 is exposed from the side surface of the encapsulating resin 140. A step portion 102a is formed at the corner portion between the lower surface 102b of the lead and the end face 102s of the lead.

The metal film 150 is continuously formed on the lower surface 102b and the step portion 102a of the lead 102. The metal film 150 is exposed from the encapsulating resin 140 and functions as an external terminal.

FIG. 2B is an enlarged view of part A in FIG. 2A. As illustrated in FIG. 2B, the lower surface 102b of the lead 102 is formed at a position above with a height t1 from the lower surface 140b of the encapsulating resin 140. The height t1 is not particularly limited, but for example, it is 1 μm or more and 10 μm or less. The thickness t2 of the metal film 150 is 10 μm or more and 50 μm or less, and the lower surface of the metal film 150 protrudes slightly from the lower surface of the encapsulating resin 140. The thickness t2 of the metal film 150 may be changed as appropriate. The material of the metal film 150 may be any material with good solder wettability, for example, lead, bismuth, tin, copper, silver, palladium, gold, or alloys of these may be mentioned.

As a result, the lower surface 102b of the lead 102 is formed at a position above the lower surface 140b of the encapsulating resin 140, creating a structure where the stress generated due to the difference in thermal expansion coefficients between the encapsulating resin 140 and the mounting substrate does not concentrate at the interface between the lower surface 102b of the lead 102 and the metal film 150. Thus, this semiconductor device 100 may suppress the occurrence of cracks at the interface between the lead 102 and the metal film 150, and may ensure bonding reliability with the mounting substrate.

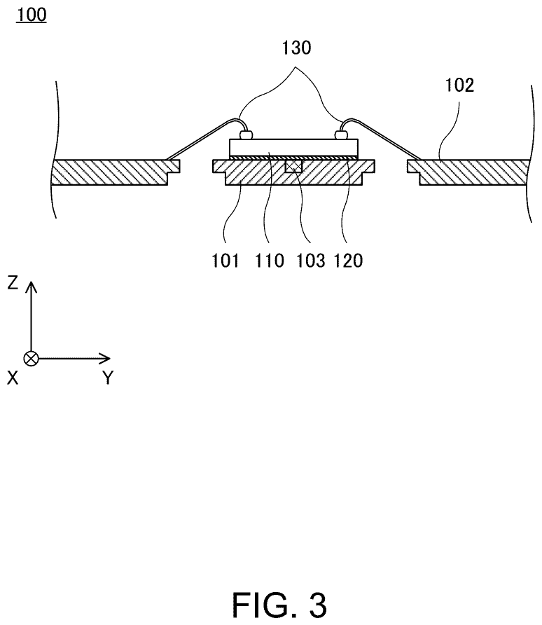

The manufacturing process of the semiconductor device 100 is described with reference to FIG. 3 to FIG. 5.

As illustrated in FIG. 3, the semiconductor chip 110 is fixed to the upper surface of the die pad 101 with conductive adhesive 120. Subsequently, a plurality of electrode pads (not shown) formed on the upper surface of the semiconductor chip 110 are electrically connected to the upper surfaces of a plurality of leads 102 with conductive wires 130. In this embodiment, the die pad 101 and the plurality of leads 102 are formed of the same copper alloy material and possess an integrated lead frame structure.

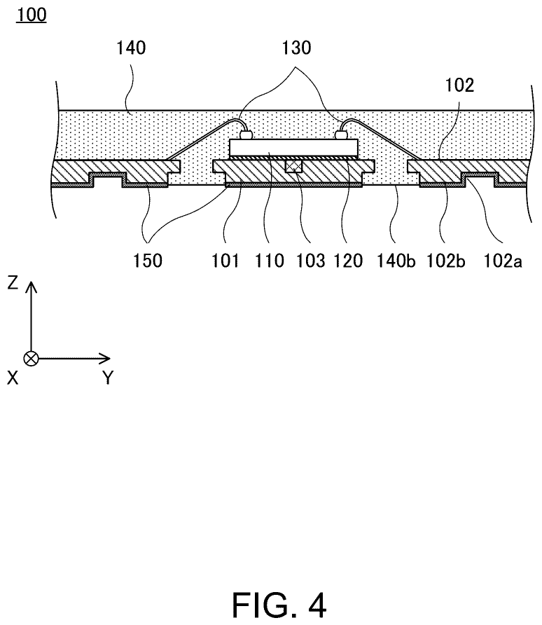

Next, as illustrated in FIG. 4, the lead frame is held between two molds (not shown), and encapsulating resin is injected into the interior of the molds and solidified to encapsulate. The lower surface of the die pad 101 and the lower surface 102b of the lead 102 are exposed from the encapsulating resin 140.

Subsequently, using a dicing device, a first cutting process is performed to form the step portion 102a of the lead 102 to a predetermined depth. The first cutting process cuts the depth t4 of the step portion 102a from the lower surface 102b of the lead 102 to a thickness of 5% to 80% of the thickness t3 of the lead 102.

Next, by etching using a chemical solution, the lower surface 102b of the lead 102, the step portion 102a, and the lower surface of the die pad 101 are formed at a position above the lower surface of the encapsulating resin. In the first cutting process, burrs of copper alloy, which is the material of the lead 102, may occur on the step portion 102a and lower surface 102b of the lead 102, and these burrs may cause short circuits between adjacent leads. Thus, by etching using a chemical solution, it is possible to remove these burrs and suppress the occurrence of short circuits between leads. Examples of the chemical solution include sulfuric acid peroxide and hydrochloric acid peroxide.

Subsequently, a metal film 150 is formed on the lower surface 102b of the lead 102, the step portion 102a, and the lower surface of the die pad 101 exposed from the encapsulating resin 140 by electrolytic plating method.

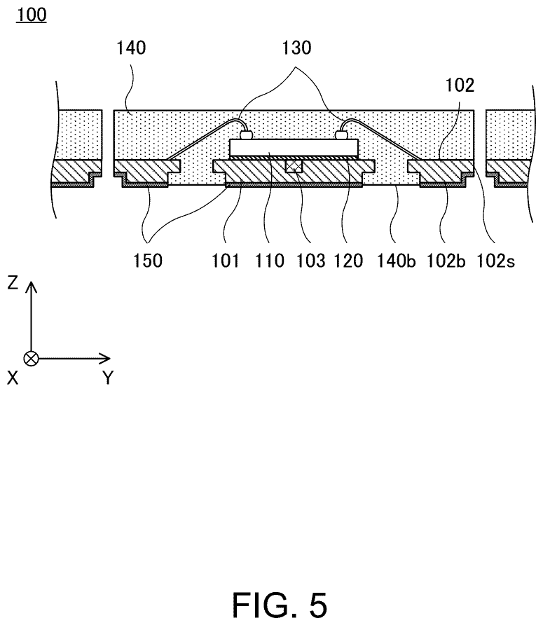

Next, as illustrated in FIG. 5, the semiconductor device 100 is manufactured by cutting and singulating the lead 102 and the encapsulating resin 140 at predetermined positions by a second cutting process using a dicing device. In this case, the blade width of the dicing device used in the second cutting process is narrower than the blade width used in the first cutting process. As a result, the end face 102s of the lead 102 is formed on the side surface of the encapsulating resin 140.

In this manner, in the semiconductor device 100 of the present embodiment, the lower surface of the lead 102 is formed at a position above the lower surface of the encapsulating resin, which prevents the stress generated due to the difference in thermal expansion coefficients from concentrating at the interface between the lead 102 and the metal film 150. As a result, the semiconductor device 100 may suppress the occurrence of cracks at the interface between the lead 102 and the metal film 150, and may ensure bonding reliability with the mounting substrate even in a non-lead type package.

### Second Embodiment

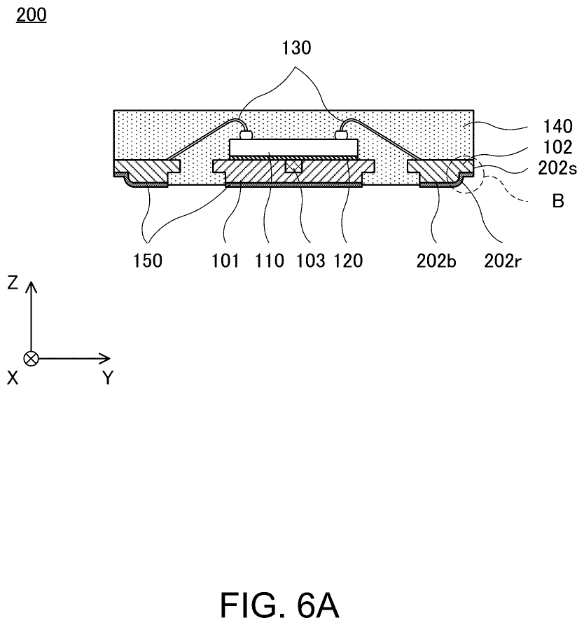

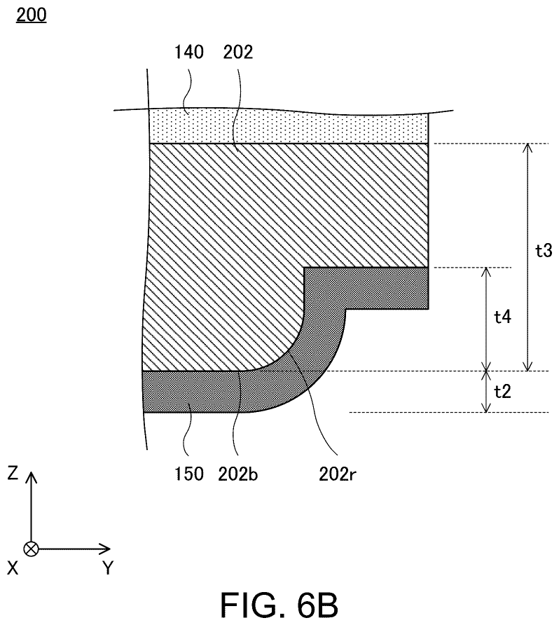

FIG. 6A is a schematic side view (perspective view) illustrating the semiconductor device according to the second embodiment of the present invention, and FIG. 6B is an enlarged view of part B in FIG. 6A.

As illustrated in FIG. 6A and FIG. 6B, the semiconductor device 200 according to the second embodiment of the present invention is similar to the first embodiment of the present invention, except that a chamfering portion 202r is formed at the corner portion between the lower surface 202b and the step portion 202a of the lead 202. Chamfering means removing the corner portion, and in the second embodiment, it is done as rounding processing to add roundness to the corner portion, but it is also possible to provide one or more angled surfaces at the corner portion.

In a structure having a corner portion between the lower surface 202b and the step portion 202a of the lead 202, stress generated due to differences in thermal expansion coefficients concentrates at the corner portion. In the configuration shown in FIG. 6A and FIG. 6B, in the case of connecting the lead 202 and the mounting substrate, it is possible to suppress the concentration of stress on the corner portion, and it is also possible to improve the climbing of solder from the lower surface 202b of the lead 202 to the step portion 202a.

For this reason, the semiconductor device 200 according to the second embodiment of the present invention may ensure bonding reliability with the mounting substrate even in the case of a non-lead type package.

The present invention has been described with respect to one embodiment, but the present invention is not limited to this embodiment and includes designs within the scope that do not depart from the gist of the present invention.

For example, in this embodiment, the package of the semiconductor device is described as a DFN package, but it is not limited to this and may be other packages. The semiconductor chip is mounted on the upper surface of the die pad by adhering it with a conductive adhesive or the like, but the present invention is not limited to this and the semiconductor chip may be mounted on a resin film. The die pad may not exist. Further, the embodiment uses conductive wires for electrical connection between the lead and the semiconductor chip, but it may also be in a flip chip configuration. In the case of this flip chip configuration, the die pad no longer exists, and bumps formed on the upper surface of the semiconductor chip may be used for electrical connection between the lead and the semiconductor chip.

Further, the material of the lead frame is described as copper alloy, but it is not limited to this and may be other materials. The method of forming the metal film is described as electrolytic plating method, but electroless plating method may also be used.

What is claimed is:

1. A semiconductor device, comprising:
a semiconductor chip;
a plurality of leads arranged apart from each other around the semiconductor chip in a plan view and extending from the semiconductor chip side;
an encapsulating resin forming an outer shape such that at least lower surfaces and end faces of the plurality of leads are respectively exposed; and
a metal film formed on a lower surface of the lead;
wherein a lower surface of the lead is formed at a position above a lower surface of the encapsulating resin.

2. The semiconductor device according to claim 1, wherein the lead comprises a step portion formed at a corner portion between a lower surface and an end face of the lead.

3. The semiconductor device according to claim 2, wherein the lead comprises a chamfering portion formed at a corner portion between a lower surface of the lead and the step portion.

4. The semiconductor device according to claim 3, wherein the chamfering portion is subjected to rounding processing.

5. The semiconductor device according to claim 3, wherein the chamfering portion is composed of a surface having an inclination.

6. The semiconductor device according to claim 2, wherein a height of the step portion is ½ or more of a thickness of the lead.

7. The semiconductor device according to claim 3, wherein a height of the step portion is ½ or more of a thickness of the lead.

8. The semiconductor device according to claim 4, wherein a height of the step portion is ½ or more of a thickness of the lead.

9. The semiconductor device according to claim 5, wherein a height of the step portion is ½ or more of a thickness of the lead.
